(19) United States
(12) Patent Application Publication
(10) Pub. No.: US 2011/0175155 A1
(43) Pub. Date: Jul. 21, 2011

(54) NONVOLATILE SEMICONDUCTOR MEMORY DEVICE

(75) Inventor: Toshitake Yaegashi, Yokohama-shi (JP)

(73) Assignee: Kabushiki Kaisha Toshiba, Tokyo (JP)

(21) Appl. No.: 12/881,730

(22) Filed: Sep. 14, 2010

(30) Foreign Application Priority Data
Jan. 19, 2010 (JP) 2010-009237

(51) Int. Cl. H01L 29/792

(52) U.S. Cl. 257/324; 257/E29.309

(57) ABSTRACT

In one embodiment, a nonvolatile semiconductor memory device includes a plurality of memory cell transistors disposed on device regions. Each of the memory cell transistors includes a tunnel insulator disposed on a device region, a charge storage layer disposed on the tunnel insulator, and formed of an insulator, a block insulator disposed on the charge storage layer, and a gate electrode disposed on the block insulator. The gate electrode of each memory cell transistor is isolated by an insulator from the gate electrode of an adjacent memory cell transistor adjacent in a gate length direction. Further, the block insulator is disposed on the device region extending in the gate length direction, and continuously disposed in regions under the gate electrodes of the memory cell transistors and in regions between the gate electrodes of the memory cell transistors. Further, the block insulator disposed in the regions between the gate electrodes includes a thin portion which has a smaller thickness than the block insulator formed in the regions under the gate electrodes.

### CROSS REFERENCE TO RELATED APPLICATION

This application is based upon and claims the benefit of priority from the prior Japanese Patent Application No. 2010-9237, filed on Jan. 19, 2010, the entire contents of which are incorporated herein by reference.

### FIELD

Embodiments described herein relate to a nonvolatile semiconductor memory device, for example, to the structure of a block insulator of a memory cell transistor.

### BACKGROUND

A known example of a nonvolatile semiconductor memory is a MONOS memory which includes MONOS cells as memory cell transistors. The MONOS memory includes device regions disposed on a semiconductor substrate and partitioned by isolation regions, and includes a tunnel insulator, a charge storage layer, a block insulator, and a gate electrode stacked on a device region so as to form a MONOS cell.

In a case where a plurality of gate electrodes are arranged on one device region like a NAND-type nonvolatile memory, block insulators between the gate electrodes are removed at the time of gate processing so that only block insulators under the gate electrodes remain. In this case, the leak characteristic of the block insulators is deteriorated due to a processing damage entering into edges of the block insulators, so that the data retention characteristic of the memory cell transistors is deteriorated.

On the other hand, an erase operation to the MONOS cell is performed by a hole injection from the semiconductor substrate via the tunnel insulator into the charge storage layer. At this time, the erase operation to the MONOS cell cannot be performed sufficiently due to an electron injection from the gate electrode via the block insulator into the charge storage layer.

To solve this problem, a high-k layer having a higher permittivity than the tunnel insulator is often used as the block insulators, and a metal having a larger work function than silicon is often used as the gate electrodes. However, in a case where the block insulators between the gate electrodes as well as the block insulators under the gate electrodes remain, the permittivity of insulators between adjacent memory cell transistors becomes greater due to the block insulators formed of the high-k layer. In this case, a parasitic gate effect becomes greater, and fluctuations in the threshold voltage of the memory cell transistors become larger.

JP-A 2002-26153 (KOKAI) describes an example of a semiconductor memory in which the block insulators between the gate electrodes remain as well as the block insulators under the gate electrodes.

### BRIEF DESCRIPTION OF THE DRAWINGS

FIG. 1 is a circuit diagram showing the structure of a nonvolatile semiconductor memory device of a first embodiment;

FIG. 2 is a plan view showing the structure of the nonvolatile semiconductor memory device of the first embodiment;

FIG. 3 is a side cross-sectional view taken along line A-A′ shown in FIG. 2;

FIGS. 4 and 5 are side cross-sectional views taken along line B-B′ shown in FIG. 2;

FIGS. 6A to 7B are side cross-sectional view for explaining a method of manufacturing the nonvolatile semiconductor memory device of the first embodiment;

FIG. 8 is a side cross-sectional view showing the structure of a nonvolatile semiconductor memory device of a second embodiment;

FIG. 9 is a side cross-sectional view showing the structure of a nonvolatile semiconductor memory device of a third embodiment;

FIG. 10 is a plan view showing the structure of a nonvolatile semiconductor memory device of a fourth embodiment;

FIG. 11 is a side cross-sectional view taken along line C-C′ shown in FIG. 10; and

FIG. 12 is a side cross-sectional view taken along line D-D′ shown in FIG. 10.

### DETAILED DESCRIPTION

Embodiments will now be explained with reference to the accompanying drawings.

An embodiment described herein is, for example, a nonvolatile semiconductor memory device including a plurality of memory cell transistors disposed on device regions. Each of the memory cell transistors includes a tunnel insulator disposed on a device region, a charge storage layer disposed on the tunnel insulator, and formed of an insulator, a block insulator disposed on the charge storage layer, and a gate electrode disposed on the block insulator. The gate electrode of each memory cell transistor is isolated by an insulator from the gate electrode of an adjacent memory cell transistor adjacent in a gate length direction. Further, the block insulator is disposed on the device region extending in the gate length direction, and continuously disposed in regions under the gate electrodes of the memory cell transistors and in regions between the gate electrodes of the memory cell transistors. Further, the block insulator disposed in the regions between the gate electrodes includes a thin portion which has a smaller thickness than the block insulator formed in the regions under the gate electrodes.

### First Embodiment

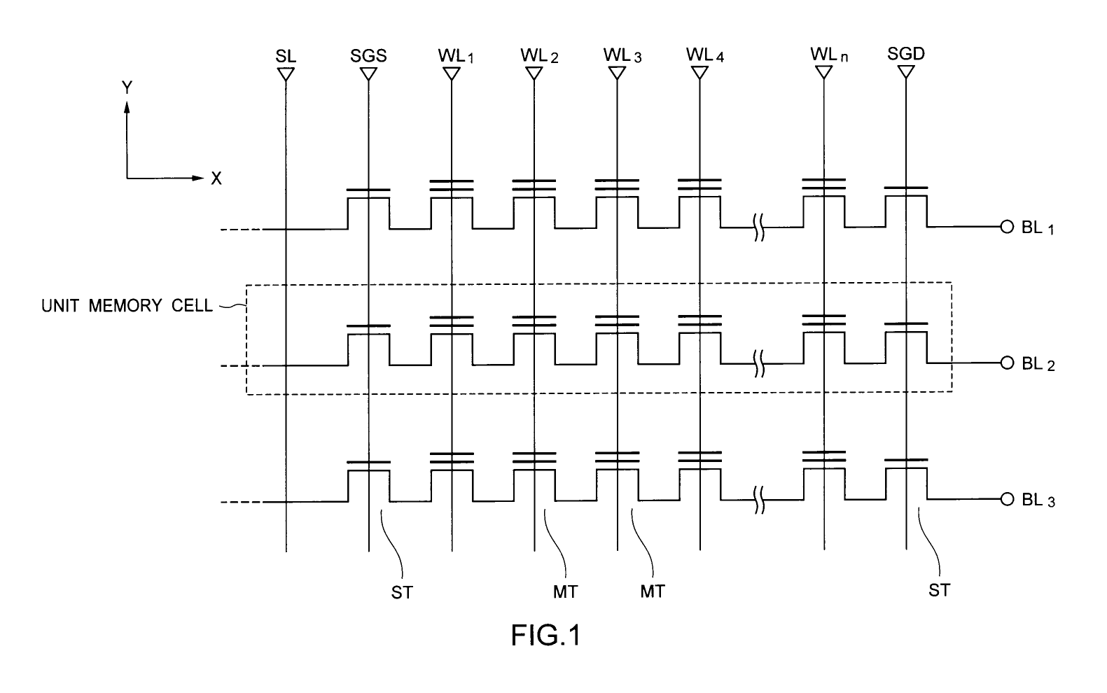

FIG. 1 is a circuit diagram showing the structure of a nonvolatile semiconductor memory device of a first embodiment. The semiconductor memory device of FIG. 1 is a NAND-type flash memory.

As shown in FIG. 1, the semiconductor memory device of this embodiment includes a plurality of unit memory cells. The unit memory cells form a memory cell block, and a plurality of memory cell blocks form a memory cell array. FIG. 1 shows an X direction and a Y direction, which are parallel to the surface (principal plane) of a substrate of the semiconductor memory device, and are orthogonal to each other.

FIG. 1 shows word lines WL₁ to WLₙ (hereinafter, unless otherwise specified, n is a positive integer of two or more), control lines SGS and SGD, and a source line SL which extend in the Y direction, and bit lines BL₁ to BL₃ which extend in the X direction. As shown in FIG. 1, the word lines WL₁ to WLₙ, the control lines SGS and SGD, and the source line SL cross the bit lines BL₁ to BL₃.

As shown in FIG. 1, each of the unit memory cells includes a plurality of memory cell transistors MT connected in series, and select transistors ST connected to both ends of these memory cell transistors MT. Each of the unit memory cells is provided between a bit line connected to a sense amplifier (not shown) and a source line.

The word lines WL₁ to WLₙ are connected to control gates of the first to the nth memory cell transistors MT connected to the bit lines BL₁ to BL₃. The control line SGS is connected to gate electrodes of the select transistors ST on the source line SL side. The control line SGD is connected to gate electrodes of the select transistors ST on the bit lines BL₁ to BL₃ side.

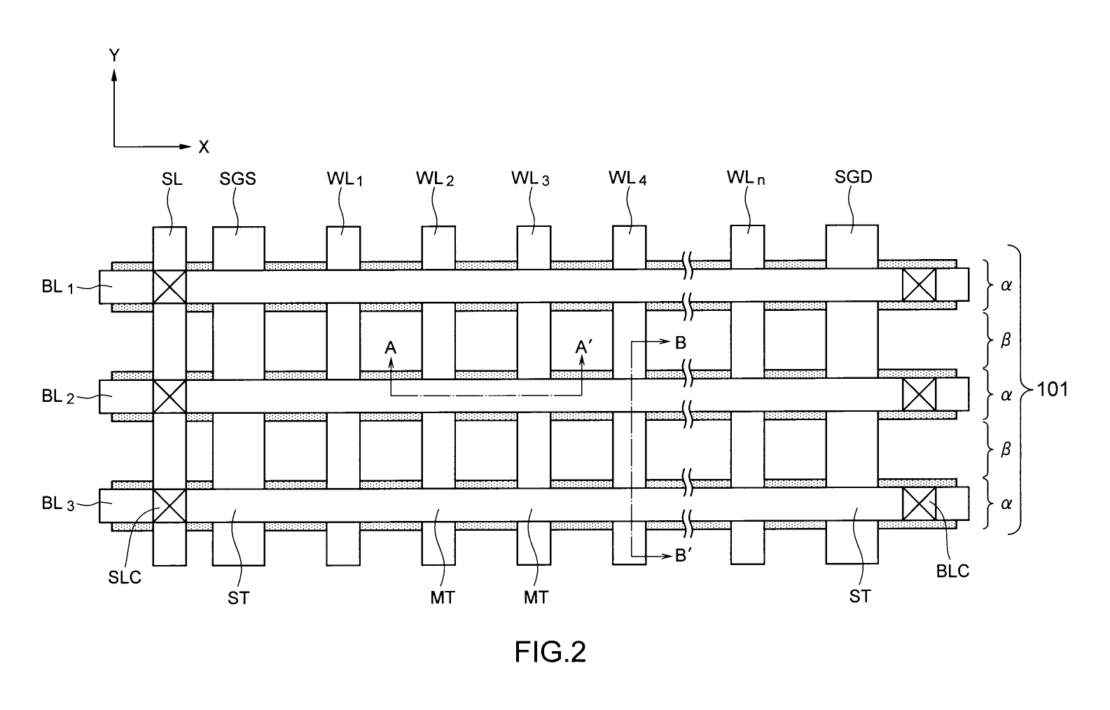

FIG. 2 is a plan view showing the structure of the nonvolatile semiconductor memory device of the first embodiment. FIG. 2 is a plan view corresponding to the circuit diagram of FIG. 1.

As shown in FIG. 2, in the semiconductor memory device of this embodiment, the word lines WL₁ to WLₙ, the control lines SGS and SGD, and the source line SL are arranged in parallel so as to be spaced from each other in the X direction. The bit lines BL₁ to BL₃ are arranged in parallel so as to be spaced from each other in the Y direction. FIG. 2 shows source line contacts SLC provided at the crossing points of the source line SL and the bit lines BL₁ to BL₃. FIG. 2 further shows bit line contacts BLC provided on the bit lines BL₁ to BL₃ between the control line SGD and the sense amplifier (not shown).

FIG. 2 further shows device regions α corresponding to AA (active area) regions, and isolation regions β corresponding to STI (shallow trench isolation) regions. The device regions α and the isolation regions β extend in the X direction, and are alternately provided along the Y direction.

The isolation regions β are realized by STI insulators formed on a substrate 101. The device regions α are regions in which the substrate 101 is isolated by the isolation regions β and which are partitioned by the isolation regions β in the Y direction. The memory cell transistors MT, the select transistors ST, and the bit lines BL₁ to BL₃ are formed on the device regions α. The bit lines BL₁ to BL₃ are arranged above the word lines WL₁ to WLₙ and the control lines SGS and SGD.

In FIGS. 1 and 2, the X direction is a gate length direction of the memory cell transistors MT and the select transistors ST. The Y direction is a channel width direction of the memory cell transistors MT and the select transistors ST.

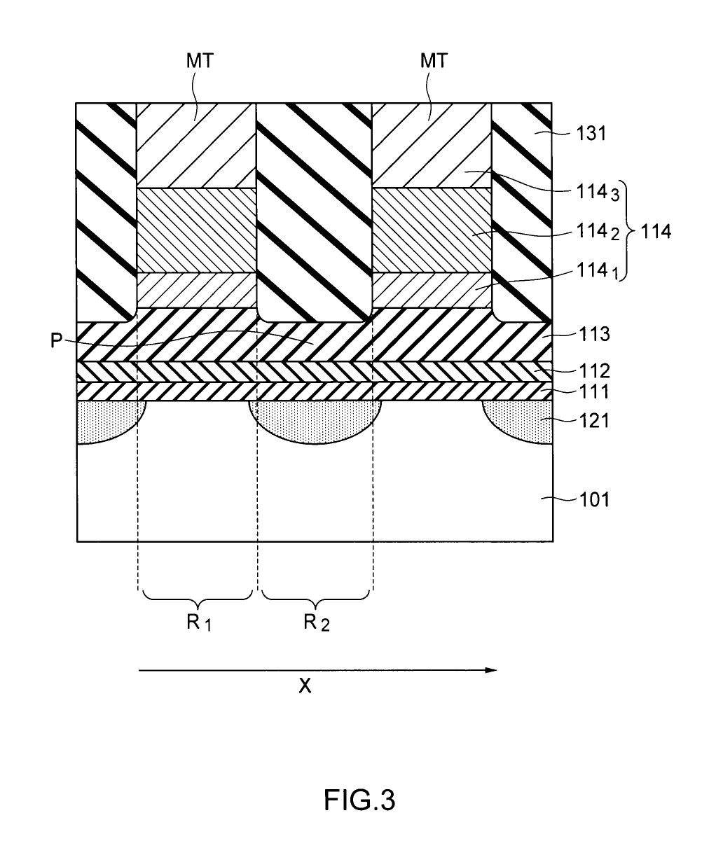

FIG. 3 is a side cross-sectional view showing the structure of the nonvolatile semiconductor memory device of the first embodiment. FIG. 3 is a side cross-sectional view taken along line A-A′ shown in FIG. 2. The line A-A′ direction is the gate length direction of the memory cell transistors MT and the select transistors ST.

FIG. 3 shows a plurality of memory cell transistors MT formed on the substrate 101 (here, two memory cell transistors MT are shown). These memory cell transistors MT are formed on the same device region a shown in FIG. 2. The substrate 101 of this embodiment is a semiconductor substrate, e.g., a silicone substrate.

As shown in FIG. 3, each of the memory cell transistors MT includes a tunnel insulator 111, a charge storage layer 112, a block insulator 113, and a gate electrode 114, which are successively disposed on the substrate 101. The charge storage layer 112 is formed of an insulating layer having a charge trap function, e.g., a silicon nitride. The gate electrode 114 is a stack layer including a first electrode layer 114₁, a second electrode layer 114₂, and a third electrode layer 114₃, which are successively formed on the block insulator 113.

Source and drain diffusion layers 121 are formed in the surface of the substrate 101 so as to sandwich the memory cell transistors MT. A buried insulator 131 for isolating the memory cell transistors MT is buried between the memory cell transistors MT adjacent in the gate length direction. The buried insulator 131 is an example of an insulator of the disclosure.

Here, the structure of the semiconductor memory device shown in FIG. 3 will be described in more detail.

In FIG. 3, the gate electrode 114 of each memory cell transistor MT is isolated by the buried insulator 131 from the gate electrode 114 of the adjacent memory cell transistor MT adjacent in the gate length direction.

On the other hand, the block insulator 113 of each memory cell transistor MT is not isolated from the block insulator 113 of the adjacent memory cell transistor MT adjacent in the gate length direction, and is integrated with the block insulator 113 of the adjacent memory cell transistor MT. As shown in FIG. 3, the block insulator 113 of this embodiment is provided on a device region a (FIG. 2) extending in the gate length direction, and continuously provided in regions R₁ under the gate electrodes 114 and regions R₂ between the gate electrodes 114.

Further, the block insulator 113 provided in the regions R₂ between the gate electrodes 114 includes thin portions P having a smaller thickness than the block insulator 113 provided in the regions R₁ under the gate electrodes 114. In this embodiment, as shown in FIG. 3, the block insulator 113 has a shape having tapers at the boundaries between the regions R₁ and the regions R₂, and is gradually thinner from a region R₁ to a region R₂. Substantially the entire block insulator 113 in the regions R₂ between the gate electrodes 114 becomes the thin portions P.

In FIG. 3, similarly to the block insulator 113, the charge storage layer 112, and the tunnel insulator 111 are also disposed on the device region α (FIG. 2) extending in the gate length direction, and continuously disposed in the regions R₁ under the gate electrodes 114 and the regions R₂ between the gate electrodes 114.

The advantage of the semiconductor memory device shown in FIG. 3 will be described.

As described above, in this embodiment, the block insulator 113 disposed in the regions R₂ between the gate electrodes 114 includes the thin portions P having a smaller thickness than the block insulator 113 disposed in the regions R₁ under the gate electrodes 114. Consequently, in this embodiment, as compared with when the thin portions P are not provided in the regions R₂, the acceleration voltage of ion implantation need not be increased when performing ion implantation for forming the source and drain regions after gate processing. Consequently, in this embodiment, deterioration of the short channel characteristic of the memory cell transistors MT can be prevented.

Further, in this embodiment, the block insulator 113 is disposed on the device region α extending in the gate length direction, and continuously disposed in the regions R₁ under the gate electrodes 114 and the regions R₂ between the gate electrodes 114. Consequently, in this embodiment, processing damage entering into the edges of the block insulator 113 between the gate electrode 114 and the charge storage layer 112 at the time of gate processing can be avoided. Consequently, in this embodiment, deterioration of the leak characteristic of the block insulator 113 due to processing damage to the edge of the gate electrode 114, and deterioration of the data retention characteristic of the memory transistor MT can be prevented.

In this embodiment, it is likeable that the block insulator 113 be formed of a material having a higher permittivity than the tunnel insulator 111. Consequently, in the erase operation to the memory cell transistor MT, the electron injection from the gate electrode 114 via the block insulator 113 into the charge storage layer 112 can be suppressed, and the erase characteristic of the memory cell transistor MT can be improved. In addition, in this embodiment, portions of the block insulator 113 in the regions R₂ between the gate electrodes 114 remain. Therefore, although the block insulator 113 is formed of the material having a higher permittivity than the tunnel insulator 111, deterioration of the data retention characteristic of the memory cell transistor MT can be prevented. Moreover, deterioration of the short channel characteristic can also be prevented.

Further, in this embodiment, it is likeable that the block insulator 113 be formed of a material having a higher permittivity than the buried insulator 131. Consequently, in this embodiment, the permittivity of the insulating layer between the gate electrodes 114 of the adjacent memory cell transistors MT becomes relatively lower. Consequently, in this embodiment, fluctuations in the threshold voltage of each memory cell transistor MT due to the parasitic gate effect of the adjacent memory cell transistor MT can be prevented.

An example of the tunnel insulator 111 and the buried insulator 131 includes a silicon oxide. An example of the block insulator 113 in this case includes a high-k layer such as an Al₂O₃ layer.

In the case where the thickness of the block insulator 113 in the regions R₁ under the gate electrodes 114 is D[nm], it is likeable that the thickness of the thin portions P be in the range between 3 [nm] and D−3 [nm] (D>6 [nm]). In the nonvolatile semiconductor memory device in which the charge storage layer 112 is an insulator, charges as data are trapped into the charge storage layer 112 in the regions R₂ near the portion in which the region R₁ and the region R₂ are contacted. In the case where the thickness of the thin portions P is smaller than 3 [nm], the thin portions P are too thin thereby causing a direct tunneling via the charge storage layer 112 in the regions R₂ near the portion in which the region R₁ and the region R₂ are contacted and via the portions P. As a result, the data retention characteristic of the memory transistors MT can be deteriorated.

In the case where the thickness of the thin portions P is larger than D−3 [nm], the thin portions P are too thick, so that the ion implantation for forming the source and drain regions may be hard to perform. It is likeable that the thickness of the thin portions P be about half of the thickness of the block insulator 113 in the regions R₁ under the gate electrodes 114, i.e., D/2 [nm].

In this embodiment, the thickness of the block insulator 113 is set to 20 nm. In this case, it is likeable that the thickness of the thin portions P be 3 to 17 mn, in particular, 10 nm.

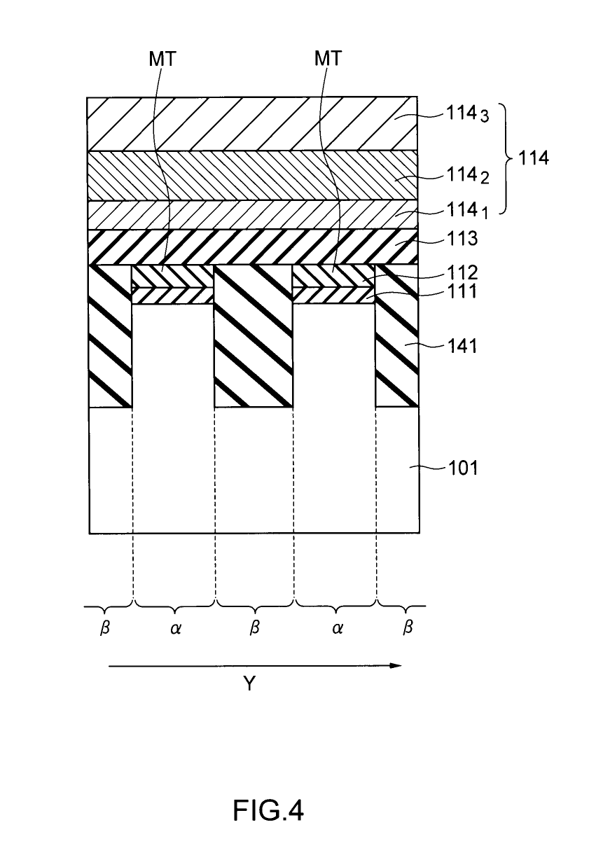

FIG. 4 is a side cross-sectional view showing the structure of the nonvolatile semiconductor memory device of the first embodiment. FIG. 4 is a side cross-sectional view taken along line B-B′ shown in FIG. 2. The line B-B′ direction is the channel width direction of the memory cell transistors MT and the select transistors ST.

FIG. 4 shows STI insulators 141 disposed on the substrate 101. The regions occupied by the STI insulators 141 correspond to the isolation regions β of FIG. 2. The regions between the STI insulators 141 correspond to the device regions α of FIG. 2.

Each of the memory cell transistors MT has the tunnel insulator 111 and the charge storage layer 112 which are successively disposed on the substrate 101 so as to be sandwiched between the STI insulators 141. Also, each of the memory cell transistors MT has the block insulator 113 and the gate electrode 114 which are successively disposed on the charge storage layer 112 so as to be extended on the substrate 101 and the STI insulators 141. The block insulator 113 and the gate electrode 114 are continuously disposed on the substrate 101 and the STI insulators 141, i.e., on the device regions α and the isolation regions β. The gate electrode 114 of the memory transistors MT is shareably connected so as to form the word line WL (FIG. 2).

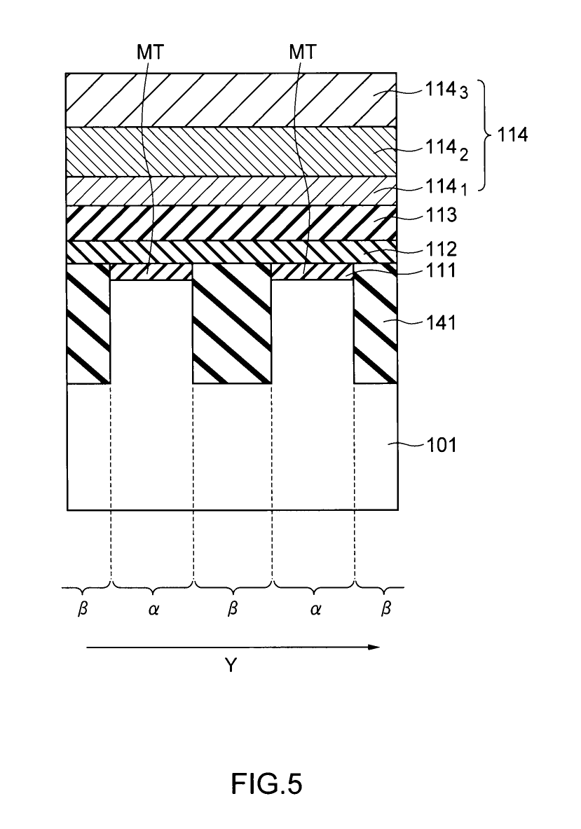

In this embodiment, instead of the structure shown in FIG. 4, the structure shown in FIG. 5 may be used. Similarly to FIG. 4, FIG. 5 is a side cross-sectional view showing the structure of the nonvolatile semiconductor memory device of the first embodiment. In FIG. 4, the charge storage layer 112 is disposed between the STI insulators 141. On the other hand, in FIG. 5, the charge storage layer 112 is continuously disposed on the substrate 101 and the STI insulators 141. As a result, the lower surface of the block insulator 113 is disposed on the entire upper surface of the charge storage layer 112.

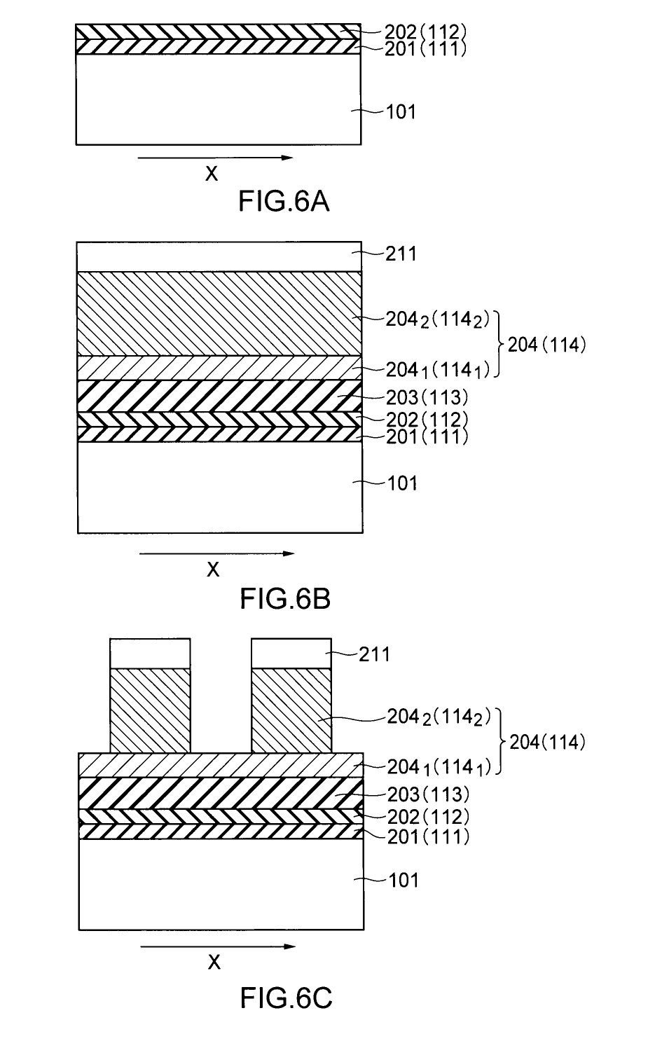

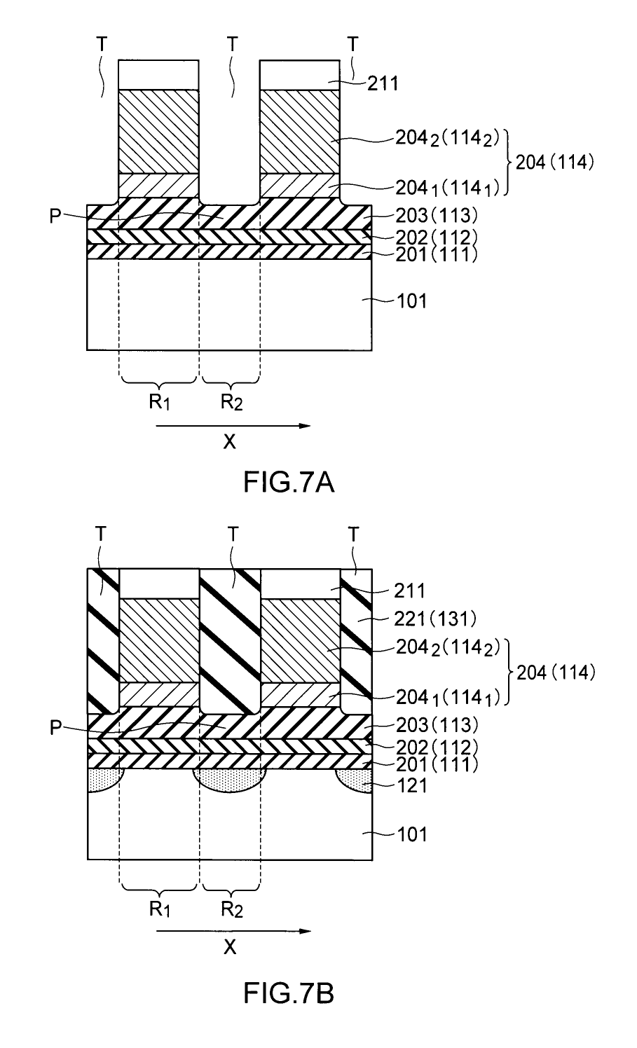

FIGS. 6A to 7B are side cross-sectional views for explaining a method of manufacturing the nonvolatile semiconductor memory device of the first embodiment. FIGS. 6A to 7B are side cross-sectional views taken along line A-A′ shown in FIG. 2.

A well channel region (not shown) for the memory cell transistors MT is formed in the substrate 101 by ion implantation. The substrate 101 is a silicon substrate, for example.

As shown in FIG. 6A, a first insulating layer 201 as the material of the tunnel insulator 111 is formed on the surface of the substrate 101. The first insulating layer 201 is a silicon oxide, and is formed by thermal oxidation, for example.

As shown in FIG. 6A, a second insulating layer 202 as the material of the charge storage layer 112 is formed on the first insulating layer 201. The second insulating layer 202 is a silicon nitride, and is formed by CVD (chemical vapor deposition), for example.

Although not shown, a mask material, which is, for example, a stack layer including a silicon oxide and a silicon nitride, is then stacked on the second insulating layer 202. A resist pattern in which isolation regions are opened is formed on the mask material by lithography. The mask material, the second insulating layer 202, the first insulating layer 201, and the substrate 101 are successively etched to form isolation trenches in the substrate 101. Isolation insulators (STI insulators) of silicon oxides are buried into the isolation trenches, and are planarized by CMP (chemical mechanical polishing). The height of the upper surface of the isolation insulators is then adjusted by etching to remove the mask material. In this way, the STI insulators 141 shown in FIG. 4 or 5 are formed on the substrate 101.

As shown in FIG. 6B, a third insulating layer 203 as the material of the block insulator 113 is formed on the second insulating layer 202. The third insulating layer 203 is an Al₂O₃ layer, for example.

As shown in FIG. 6B, a first electrode layer 204₁ of an electrode layer 204 as the material of the first electrode layer 114₁ of the gate electrode 114 is formed on the third insulating layer 203. The first electrode layer 204₁ is a TaN layer, for example.

As shown in FIG. 6B, a second electrode layer 204₂ of the electrode layer 204 as the material of the second electrode layer 114₂ of the gate electrode 114 is formed on the first electrode layer 204₁. The second electrode layer 204₂ is a polysilicon layer, for example.

As shown in FIG. 6B, a mask material 211 for gate processing is formed on the second electrode layer 204₂. The mask material 211 is a silicon nitride, for example.

A resist pattern for gate processing electrode is formed on the mask material 211 by lithography. As shown in FIG. 6C, the mask material 211 and the second electrode layer 204₂ are then successively etched.

As shown in FIG. 7A, the first electrode layer 204₁ and portions of the third insulating layer 203 are etched by using the mask material 211. Trenches T which penetrate the first electrode layer 204₁ and the second electrode layer 204₂ and in which the third insulating layer 203 is exposed are formed. Etching of the third insulating layer 203 may be continuously performed under the same conditions as the etching of the first electrode layer 204₁, or may be performed as an additional process by changing the etching conditions of the first electrode layer 204₁. In the case where a TaN layer is used as the first electrode layer 204₁ and an Al₂O₃ layer is used as the third insulating layer 203, etching of the TaN layer may be performed by plasma etching using a mixed gas of BCl₃ and N₂, and after that, the Al₂O₃ layer may be etched without changing the conditions.

The etching of the TaN layer may be performed by plasma etching using a mixed gas of BCl₃ and N₂, and after that, by changing the etching conditions, etching of the Al₂O₃ layer may be performed by reactive ion etching with plasma including BCl₃. As a result, the etching can be performed under the conditions in which the etching rates of the TaN layer and the Al₂O₃ layer are large. Consequently, gate electrode processing can be performed for a short time.

Further, the etching of the first electrode layer 204₁, the second electrode layer 204₂, and the third insulating layer 203 may be continuously performed by using the etching conditions of the second electrode layer 204₂. In the case where the second electrode layer 204₂ is a polysilicon layer, the etching of the first electrode layer 204₁ and the third insulating layer 203 can be performed using an F, Cl, or Br etching gas. As a result, the etching of the first electrode layer 204₁, the second electrode layer 204₂, and the third insulating layer 203 can be performed without changing the etching conditions.

In this embodiment, portions of the third insulating layer 203 are etched, so that the thin regions P shown in FIG. 3 are formed in the bottom portions of the trenches T. FIG. 7A shows the regions R₁ under the gate electrodes 114, and the regions R₂ between the gate electrodes 114 including the thin portions P.

The timing to stop the etching of the third insulating layer 203 can be controlled by a measurement of the etching time. The etching of the third insulating layer 203 may be performed by making an overetching somewhat larger when etching the first electrode layer 204₁. After the etching of the first electrode layer 204₁ is stopped, the etching of the third insulating layer 203 may be performed by switching the etching gases.

As shown in FIG. 7B, ion implantation of impurities is performed using the mask material 211, the first electrode layer 204₁, and the second electrode layer 204₂ as a mask to form the source and drain diffusion layers 121 in the surface of the substrate 101. At this time, the thickness of the third insulating layer 203 in the regions R₂ is smaller than that of the third insulating layer 203 in the regions R₁. Therefore, even when the ion acceleration at the time of ion implantation is low, the impurities penetrate the third insulating layer 203 in the regions R₂ and can reach the substrate 101. Then, an insulating layer 221 as the material of the buried insulator 131 is stacked on the entire surface of the substrate 101, and is planarized by CMP. Consequently, as shown in FIG. 7B, the insulating layer 221 is buried into the trenches T. The insulating layer 211 is a silicon oxide, for example.

As shown in FIG. 3, the mask material 221 is then removed. As shown in FIG. 3, the third electrode layer 114₃ of the gate electrode 114 (electrode layer 204) is then formed on the second electrode layer 114₂ of the gate electrode 114 (electrode layer 204) which is exposed by removing the mask material 211. Here, the third electrode layer 114₃ is a CoSi layer, so that the third electrode layer 114 is a low-resistance electrode layer in this embodiment.

After that, an inter layer dielectric, a contact electrode, and a interconnect layer are formed by typically known methods so as to complete the nonvolatile semiconductor memory device of this embodiment.

As described above, in this embodiment, the block insulator 113 is disposed on the device region a extending in the gate length direction, and continuously disposed in the regions R₁ under the gate electrodes 114 and the regions R₂ between the gate electrodes 114. Consequently, in this embodiment, deterioration of the leak characteristic of the block insulator 113 due to processing damage to the edges of the gate electrode 114, and deterioration of the data retention characteristic of the memory cell transistors MT can be prevented.

Further, in this embodiment, the block insulator 113 disposed in the regions R₂ between the gate electrodes 114 includes the thin portions P having a smaller thickness than the block insulator 113 disposed in the regions R₁ under the gate electrodes 114. Consequently, in this embodiment, the acceleration voltage of ion implantation need not be increased when performing ion implantation for forming the source and drain regions after gate processing. Consequently, deterioration of the short channel characteristic of the memory cell transistors MT can be prevented.

Further, in this embodiment, the block insulator 113 is preferably formed of a material having a higher permittivity than the tunnel insulator 111. Consequently, in this embodiment, in the erase operation to the memory cell transistor MT, the electron injection from the gate electrode 114 via the block insulator 113 into the charge storage layer 112 can be suppressed, and the erase characteristic of the memory cell transistor MT can be improved.

Further, in this embodiment, the block insulator 113 is preferably formed of a material having a higher permittivity than the buried insulator 131. Consequently, in this embodiment, fluctuations in the threshold voltage of each memory cell transistor MT due to the parasitic gate effect of the adjacent memory cell transistor MT can be prevented.

Second to fourth embodiments will be described below. Since these embodiments are modification of the first embodiment, these embodiments will be described by focusing on the differences from the first embodiment.

### Second Embodiment

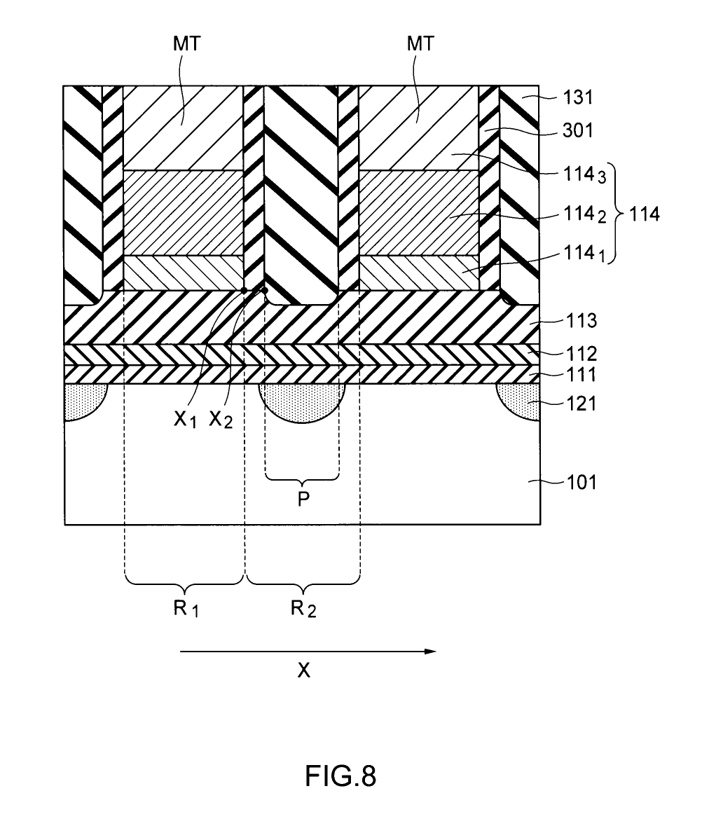

FIG. 8 is a side cross-sectional view showing the structure of a nonvolatile semiconductor memory device of a second embodiment. FIG. 8 is a side cross-sectional view taken along line A-A′ shown in FIG. 2.

In the first embodiment (FIG. 3), the block insulator 113 in the regions R₂ includes the thin portions P having a smaller thickness than the block insulator 113 in the regions R₁. In addition, in the first embodiment, substantially the entire block insulator 113 in the regions R₂ is the thin portions P.

In the second embodiment (FIG. 8), the block insulator 113 in the regions R₂ includes the thin portions P having a smaller thickness than the block insulator 113 in the regions R₁, similarly to the first embodiment. However, in the second embodiment, only parts of the block insulator 113 in the regions R₂, not the entire thereof, are the thin portions P.

Referring to FIG. 8, the detail of the structure of the semiconductor memory device of the second embodiment will be described below.

In the second embodiment, as shown in FIG. 8, sidewall insulators 301 are disposed on side surfaces of each gate electrode 114 in the gate length direction. In the process of FIG. 7A, the sidewall insulators 301 are disposed between the etching of the gate electrode 114 (electrode layer 204) and the etching of the block insulator 113 (third insulating layer 203). In the second embodiment, the sidewall insulators 301 are formed before the etching of the block insulator 113. The thin portions P are limited to the parts of the center portions of the block insulator 113 in the regions R₂, not to the entire thereof.

As a result, as shown in FIG. 8, an edge X₂ of a thin portion P in the gate length direction (more specifically, the point at which the sidewall insulator 301, the buried insulator 131, and the block insulator 113 are contacted) is provided in the position away from an edge X₁ of the gate electrode 114 in the gate length direction. Consequently, in the second embodiment, the thin portion P of the block insulator 113 in which the leak characteristic is deteriorated due to processing damage of gate processing is away from a portion directly below the gate electrode 114. Consequently, in the second embodiment, the data retention characteristic of the memory cell transistors MT can be improved.

In the second embodiment, the sidewall insulators 301 are formed before the etching of the block insulator 113. Therefore, the block insulator 113 disposed in the regions under the sidewall insulators 301 has a thickness equal to that of the block insulator 113 in the regions R₁. Furthermore, the thickness of each sidewall insulator 301 is substantially equal to the distance between the edges X₁ and X₂.

In the second embodiment, the edge X₂ of the thin portion P in the gate length direction is provided in the position away from the edge X₁ of the gate electrode 114 in the gate length direction.

On the other hand, in the first embodiment, the edge X₂ of the thin portion P in the gate length direction is provided in substantially the same position as the edge X₁ of the gate electrode 114 in the gate length direction.

The semiconductor memory device of the second embodiment can be fabricated by the following method.

Similarly to the first embodiment, as shown in FIG. 7A, the etching processing of the first electrode layer 204₁ of the electrode layer 204 is performed. At this time, the etching is ended when the first electrode layer 204₁ is removed so that the third insulating layer 203 is not etched. The sidewall insulators 301 (FIG. 8) are formed on the sidewalls of the mask material 211, the second electrode layer 204₂, and the first electrode layer 204₁. The sidewall insulators 301 are a silicon oxide, for example. Similarly to the first embodiment, the etching processing of parts of the third insulating layer 203 is then performed. After that, the mask material 211, the first electrode layer 204₁, the second electrode layer 204₂, and the sidewall insulator 301 are used as a mask to perform ion implantation of impurities. Consequently, the source and drain diffusion layers 121 are formed in the surface of the substrate 101. The following processes are performed similarly to the first embodiment, so that the semiconductor memory device of the second embodiment can be obtained.

As described above, in this embodiment, the edge X₂ of the thin portion P in the gate length direction is provided in the position away from the edge X₁ of the gate electrode 114 in the gate length direction. Consequently, the data retention characteristic of the memory cell transistors MT can be improved.

### Third Embodiment

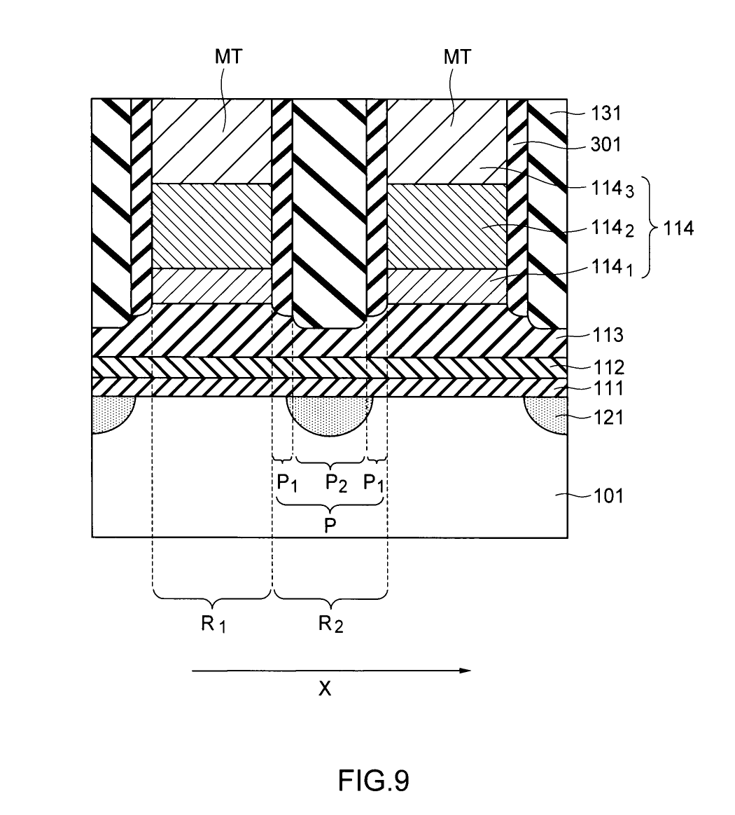

FIG. 9 is a side cross-sectional view showing the structure of a nonvolatile semiconductor memory device of a third embodiment. FIG. 9 is a side cross-sectional view taken along line A-A′ shown in FIG. 2.

In the third embodiment, as shown in FIG. 9, the sidewall insulators 301 are disposed on the side surfaces of each gate electrode 114 in the gate length direction, similarly to the second embodiment. However, in the third embodiment, each of the thin portions P includes first thin portions P₁ having a smaller thickness than the block insulator 113 in the regions R₁, and a second thin portion P₂ having a smaller thickness than the first thin portions P₁. The first thin portions P₁ are located under the sidewall insulators 301. The second thin portion P₂ is located between the first thin portions P₁. In this way, in the third embodiment, the thickness of the thin portion P is changed at two stages.

FIG. 9 shows the structure that the first thin portions P₁ are disposed in the regions under the sidewall insulators 301, and the second thin portion P₂ is disposed in the region under the buried insulator 131. In this embodiment, as shown in FIG. 9, the block insulator 113 has a shape having a taper at the boundary between a first thin portion P₁ and a second thin portion P₂, and is gradually thinner from the first thin portion P₁ to the second thin portion P₂.

Referring to FIG. 9, the advantage of the semiconductor memory device of the third embodiment will be described below.

In the second embodiment, the thin portions P are limited to the parts of the center portions of the block insulator 113 in the regions R₂. Therefore, in the second embodiment, the block insulator 113 directly below the edge of the gate electrode 114 has a sufficient thickness. Consequently, deterioration of the data retention characteristic of the memory cell transistors MT due to deterioration of the leak characteristic of the block insulator 113 can be prevented.

In the third embodiment, as shown in FIG. 9, each of the thin portions P includes the first thin portions P₁, and the second thin portion P₂. Therefore, in the third embodiment, similarly to the second embodiment, deterioration of the data retention characteristic of the memory cell transistors MT due to deterioration of the leak characteristic of the block insulator 113 can be prevented by giving a sufficient thickness to the first thin portions P₁.

Further, in the third embodiment, the center portions of the block insulator 113 in the regions R₂ are the second thin portions P₂ having a smaller thickness than the first thin portions P₁. Therefore, in the third embodiment, as compared with the second embodiment, ion implantation for forming the source and drain regions can be easily performed. Consequently, in the third embodiment, the acceleration voltage of the ion implantation need not be increased at the time of the ion implantation as compared with the second embodiment. Consequently, the short channel characteristic of the memory cell transistors MT can be improved.

Further, in the third embodiment, the thickness of the thin portions P is changed at two stages. Consequently, the permittivity of insulators between the gate electrodes 114 can be lowered. In this case, the buried insulator 131 is formed of a material having a lower permittivity than the block insulator 113. Consequently, in the third embodiment, fluctuations in the threshold voltage of each memory cell transistor MT due to the parasitic gate effect of the adjacent memory cell transistor MT can be prevented more effectively.

The semiconductor memory device of the third embodiment can be fabricated by the following method.

Similarly to the first embodiment, as shown in FIG. 7A, the etching processing of the first electrode layer 204₁ of the electrode layer 204 and parts of the third insulating layer 203 is performed. Consequently, the thin portions P in which the entire third insulating layer 203 in the regions R₂ has the thickness of the first thin portions P₁ are formed. The sidewall insulators 301 (FIG. 9) are formed on the sidewalls of the mask material 211, the second electrode layer 204₂, the first electrode layer 204₁, and the third insulating layer 203. The mask material 211 and the sidewall insulators 301 are used as a mask to perform the etching processing of parts of the third insulating layer 203. In each thin portion P, the second thin portion P₂ is formed in the center of the thin portion P. After that, the mask material 211, the first electrode layer 204₁, the second electrode layer 204₂, and the sidewall insulators 301 are used as a mask to perform ion implantation of impurities, whereby the source and drain diffusion layers 121 are formed in the surface of the substrate 101. The following processes are performed similarly to the first embodiment, so that the semiconductor memory device of the third embodiment can be obtained.

As described above, in this embodiment, each of the thin portions P includes the first thin portions P₁ having a smaller thickness than the block insulator 113 in the regions R₁, and the second thin portion P₂ having a smaller thickness than the first thin portions P₁. Consequently, in this embodiment, the data retention characteristic of the memory cell transistors MT can be prevented, and the short channel characteristic of the memory cell transistors MT can be improved.

In the first to the third embodiments, the gate electrode 114 is a stack layer including the first electrode layer 114₁ as a TaN layer, the second electrode layer 114₂ as a polysilicon layer, and the third electrode layer 114₃ as a CoSi layer. However, the structure of the gate electrode 114 is not limited to such structure. The gate electrode 114 may be a single layer having only one electrode layer or a stack layer including two or more electrode layers.

### Fourth Embodiment

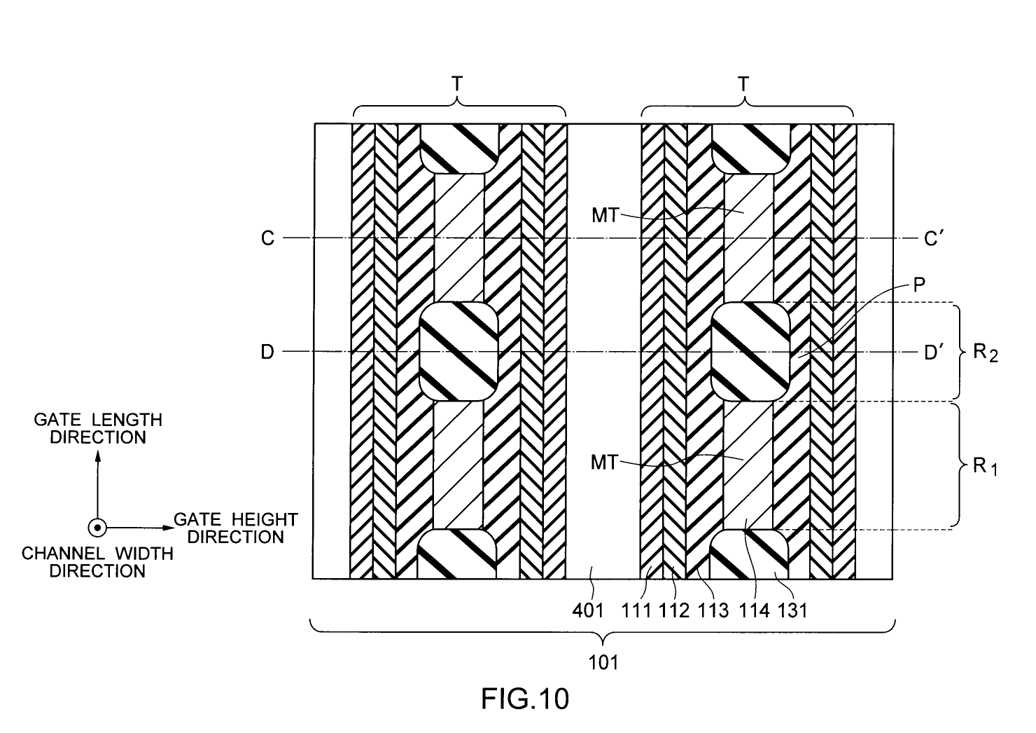

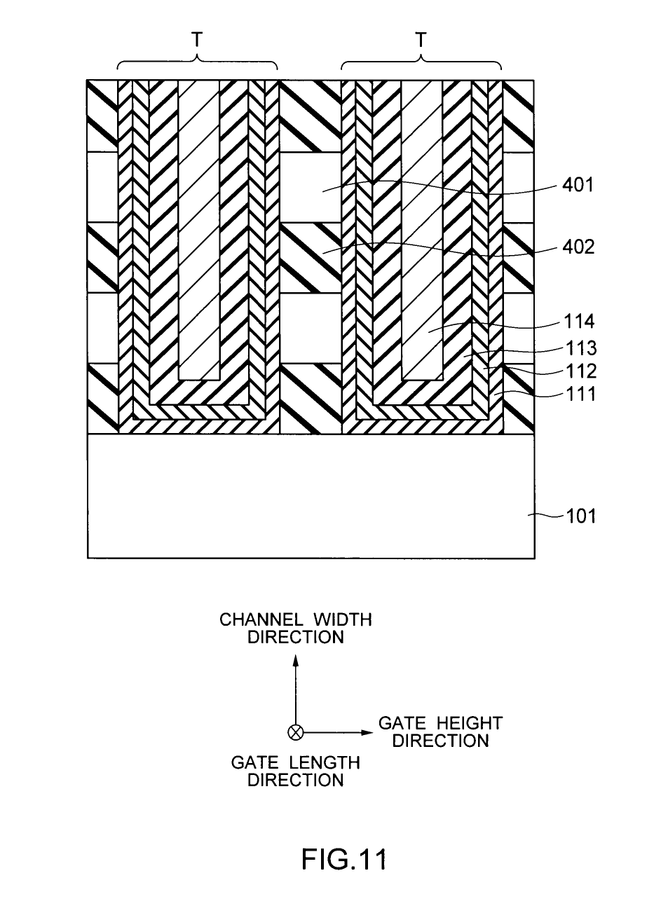

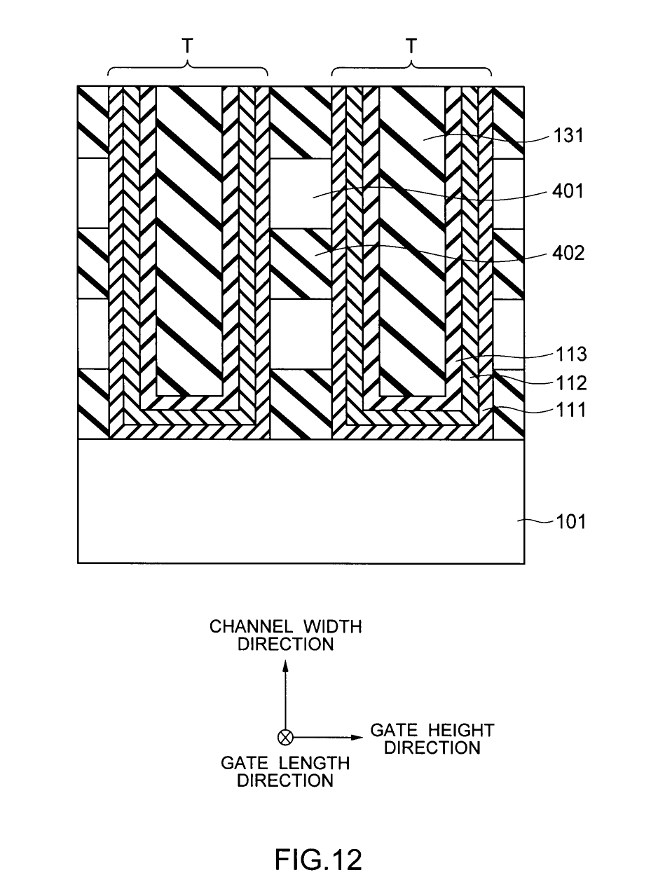

FIG. 10 is a plan view showing the structure of a nonvolatile semiconductor memory device of a fourth embodiment. FIGS. 11 and 12 are side cross-sectional views taken along line C-C′ and line D-D′ shown in FIG. 10.

In the first to the third embodiments, the memory cell transistors MT are disposed on the plane of the substrate 101. In the fourth embodiment, the memory cell transistors MT are stacked on the substrate 101 in three dimensions. For the structure in which the memory cell transistors are stacked in three dimensions, see the document “W. Kim et al., pp. 188-pp. 189 2009 symposium on VLSI technology”.

Referring to FIGS. 10 to 12, the detail of the structure of the semiconductor memory device of the fourth embodiment will be described below. In FIG. 10, a horizontal direction on the sheet, i.e., a direction parallel to line C-C′ and line D-D′, corresponds to a gate height direction of the memory cell transistors MT, and an up-and-down direction on the sheet, i.e., a direction vertical to line C-C′ and line D-D′, corresponds to the gate length direction of the memory cell transistors MT. In FIG. 10, the direction vertical to the sheet corresponds to the channel width direction of the memory cell transistors MT. The gate height direction and the gate length direction are parallel to the surface (principal plane) of the substrate of the semiconductor memory device, and the channel width direction is vertical to the surface of the substrate.

In this embodiment, as shown in the cross-sectional view taken along line C-C′ of FIG. 11, AA semiconductor layers 401 which are semiconductor layers to be the device regions, and STI insulators 402 which is insulating layers to be the isolation regions, are alternately stacked on the substrate 101. In this embodiment, the AA semiconductor layers 401 are polysilicon layers, and the STI insulators 402 are silicon insulators such as silicon oxides. Each device region (AA semiconductor layer 401) of this embodiment is defined by isolation regions (STI insulators 402) adjacent to the upper and lower surfaces of the device region.

In this embodiment, as shown in the cross-sectional view taken along line C-C′ of FIG. 11, a plurality of trenches T which penetrate the AA semiconductor layers 401 and the STI insulators 402 and extend in the gate length direction are formed on the substrate 101. The tunnel insulator 111, the charge storage layer 112, the block insulator 113, and the gate electrode 114 are successively disposed on the side surfaces of the AA semiconductor layers 401 and the STI insulators 402 exposed by each trench T and on the substrate 101. The tunnel insulator 111, the charge storage layer 112, the block insulator 113, and the gate electrode 114 are successively disposed on the side surfaces and the bottom surface of each trench T.

Consequently, as shown in FIG. 10, the memory cell transistors MT each including the tunnel insulator 111, the charge storage layer 112, the block insulator 113, and the gate electrode 114 which are successively disposed on a device region (AA semiconductor layer 401) are formed. FIG. 10 shows the tunnel insulator 111, the charge storage layer 112, the block insulator 113, and the gate electrode 114 which are disposed on side surfaces of the AA semiconductor layer 401 exposed by each trench T.

Further, in this embodiment, as shown in FIG. 10, the buried insulator 131 for isolating the gate electrodes 114 of the memory cell transistors MT is buried between the memory cell transistors MT adjacent in the gate length direction. The cross-sectional shape of the buried insulator 131 is shown in the cross-sectional view taken along line D-D′ of FIG. 12.

In FIG. 12, the tunnel insulator 111, the charge storage layer 112, and the block insulator 113 are disposed on the side surfaces of the AA semiconductor layers 401 and the STI insulators 402 exposed by each trench T and on the substrate 101. The buried insulator 131 is disposed so that the portions between the block insulators 113 are buried. In the gate height direction, the thickness of the block insulator 113 shown in FIG. 12 is smaller than that of the block insulator 113 shown in FIG. 11. As a result, in the gate height direction, the thickness of the buried insulator 131 shown in FIG. 12 is larger than that of the gate electrode 114 shown in FIG. 11.

In this embodiment, as shown in FIGS. 10 to 12, each of the AA semiconductor layers 401 and the STI insulators 402 is configured to have a band shape extending in the gate length direction by the trenches penetrating them.

The structure of the semiconductor memory device shown in FIG. 10 will be described here in more detail.

In FIG. 10, the gate electrode 114 of each memory cell transistor MT is isolated by the buried insulator 131 from the gate electrode 114 of the adjacent memory cell transistor MT adjacent in the gate length direction. This is the same as the first embodiment.

On the other hand, the block insulator 113 of each memory cell transistor MT is not isolated from the block insulator 113 of the adjacent memory cell transistor MT adjacent in the gate length direction, and is integrated with the block insulator 113 of the adjacent memory cell transistor MT. As shown in FIG. 10, the block insulator 113 of this embodiment is disposed on an AA semiconductor layer 401 extending in the gate length direction, and continuously disposed in the regions R₁ under the gate electrodes 114 and the regions R₂ between the gate electrodes 114. This is also the same as the first embodiment.

Further, the block insulator 113 disposed in the regions R₂ includes the thin portions P having a smaller thickness in the gate height direction than the block insulator 113 disposed in the regions R₁. This is also the same as the first embodiment. In this embodiment, as shown in FIG. 10, substantially the entire block insulator 113 in the regions R₂ is the thin portions P. Further, as shown in FIG. 10, the corner portions of the buried insulator 131 are arc. Further, as shown in FIG. 10, the block insulator 113 has a shape having a taper in the gate height direction at the boundary between a region R₁ and a region R₂, and is gradually thinner from the region R₁ to the region R₂.

In this embodiment, similarly to the block insulator 113, the charge storage layer 112 and the tunnel insulator 111 are disposed on the AA semiconductor layer 401 extending in the gate length direction, and continuously disposed in the regions R₁ under the gate electrodes 114 and the regions R₂ between the gate electrodes 114.

Further, in this embodiment, as shown in FIGS. 11 and 12, the tunnel insulator 111, the charge storage layer 112, the block insulator 113, and the gate electrode 114 are continuously disposed on the AA semiconductor layers 401 and on the STI insulators 402.

As described above, the block insulator 113 of this embodiment has the same structure as the block insulator 113 of the first embodiment, on the viewpoints that the block insulator 113 is disposed on a device region and continuously disposed in the regions R₁ and the regions R₂, and the block insulator 113 in the regions R₂ includes the thin portions P. Consequently, in this embodiment, similarly to the first embodiment, fluctuations in the threshold voltage of the memory cell transistor MT due to deterioration of the data retention characteristic of the memory cell transistor MT, and the parasitic gate effect of the adjacent memory cell transistor MT can be prevented. In this embodiment, similarly to the first embodiment, it is likeable that the block insulator 113 be formed of a material having a higher permittivity than the tunnel insulator 111 and the buried insulator 131.

Referring to FIG. 10, a method of manufacturing the semiconductor memory device of the fourth embodiment will be described below.

The AA semiconductor layers 401 and the STI insulators 402 are alternately stacked on the substrate 101. A plurality of trenches T which penetrates the AA semiconductor layers 401 and the STI insulators 402 and are aligned at fixed intervals in the gate height direction are formed. The tunnel insulator (silicon oxide) 111, the charge storage layer (silicon nitride) 112, the block insulator (Al₂O₃ layer) 113, and the gate electrode (polysilicon layer) 114 are successively formed on the side surfaces of the AA semiconductor layers 401 and the STI insulators 402 exposed by each trench T and on the upper surface of the substrate 101. The gate electrode 114 is patterned so as to form an opening for burying the buried insulator 131, so that the gate electrode 114 in the opening is removed by etching. At this time, similarly to the first embodiment, parts of the block insulator 113 in the regions R₂ between the gate electrodes 114 are etched so that the thin portions P can be formed. The buried insulator 131 is buried into the opening. In this way, the semiconductor memory device of the fourth embodiment can be obtained.

In this embodiment, similarly to the second embodiment, only parts of the block insulator 113 in the regions R₂ may be the thin portions P. In this embodiment, similarly to the third embodiment, each of the thin portions P may include the first thin portions P₁ and the second thin portion P₂. Similarly to the second and the third embodiments, these structures can be realized by forming the sidewall insulators on the sidewall of each gate electrode 114 after gate processing.

As described above, the block insulator 113 of this embodiment has the same structure as the block insulator 113 of the first to the third embodiments, on the viewpoints that the block insulator 113 is disposed on the device region and continuously disposed in the regions R₁ and the regions R₂, and the block insulator 113 in the regions R₂ include the thin portions P. Consequently, in this embodiment, similarly to the first to the third embodiments, fluctuations in the threshold voltage of the memory cell transistor MT due to deterioration of the data retention characteristic of the memory cell transistor MT, and the parasitic gate effect of the adjacent memory cell transistor MT can be prevented.

As described above, according to the embodiments described herein, the nonvolatile semiconductor memory device which can improve the parasitic gate effect between the adjacent memory cells can be provided. The effects obtained by the embodiments described herein are not limited to the case that the substrate 101, the tunnel insulator 111, the charge storage layer 112, the block insulator 113, the gate electrode 114, the buried insulator 131 and the like are formed of the above materials. The semiconductor memory device which is formed using other materials is also effective as long as it has the above structure.

While certain embodiments have been described, these embodiments have been presented by way of example only, and are not intended to limit the scope of the inventions. Indeed, the novel devices described herein may be embodied in a variety of other forms; furthermore, various omissions, substitutions and changes in the form of the devices described herein may be made without departing from the spirit of the inventions. The accompanying claims and their equivalents are intended to cover such forms or modifications as would fall within the scope and spirit of the inventions.

1. A nonvolatile semiconductor memory device comprising a plurality of memory cell transistors disposed on device regions, each of the memory cell transistors comprising:
a tunnel insulator disposed on a device region;
a charge storage layer disposed on the tunnel insulator, and formed of an insulator;
a block insulator disposed on the charge storage layer; and
a gate electrode disposed on the block insulator,
wherein
the gate electrode of each memory cell transistor is isolated by an insulator from the gate electrode of an adjacent memory cell transistor adjacent in a gate length direction,
the block insulator is disposed on the device region extending in the gate length direction, and continuously disposed in regions under the gate electrodes of the memory cell transistors and in regions between the gate electrodes of the memory cell transistors, and
the block insulator disposed in the regions between the gate electrodes comprises a thin portion which has a smaller thickness than the block insulator formed in the regions under the gate electrodes.

2. The device according to claim 1, wherein
an edge of the thin portion in the gate length direction is provided at a position away from an edge of the gate electrode in the gate length direction.

3. The device according to claim 2, wherein
each of the memory cell transistors further comprises sidewall insulators disposed on side surfaces of the gate electrode in the gate length direction.

4. The device according to claim 3, wherein
a thickness of the block insulator disposed in regions under the sidewall insulators is equal to a thickness of the block insulator disposed in the regions under the gate electrodes.

5. The device according to claim 3, wherein
a thickness of each sidewall insulator is substantially equal to a distance between the edge of the gate electrode in the gate length direction and the edge of the thin portion in the gate length direction.

6. The device according to claim 1, wherein
the thin portion comprises a first thin portion, and a second thin portion having a smaller thickness than the first thin portion.

7. The device according to claim 6, wherein
each of the memory cell transistors further comprises sidewall insulators disposed on side surfaces of the gate electrode in the gate length direction.

8. The device according to claim 7, wherein
the first thin portion is disposed in a region under a sidewall insulator, and
the second thin portion is disposed in a region under the insulator.

9. The device according to claim 6, wherein
the block insulator has a shape having a taper at a boundary between the first thin portion and the second thin portion.

10. The device according to claim 1, wherein
an edge of the thin portion in the gate length direction is provided in substantially the same position as an edge of the gate electrode in the gate length direction.

11. The device according to claim 1, wherein
the block insulator has a shape having a taper at a boundary between the thin portion and a portion other than the thin portion.

12. The device according to claim 1, wherein
the charge storage layer and the tunnel insulator are continuously disposed in the regions under the gate electrodes and in the regions between the gate electrodes.

13. The device according to claim 1, wherein
a thickness of the block insulator disposed in the regions under the gate electrodes is D[nm] where D>6 [nm], and
a thickness of the thin portion is in a range between 3 [nm] and D−3 [nm].

14. The device according to claim 1, wherein
the device regions are partitioned in a channel width direction orthogonal to the gate length direction by isolation regions extending in the gate length direction, and
the block insulator is continuously disposed on the isolation regions and on the device regions.

15. The device according to claim 14, wherein
the charge storage layer is continuously disposed on the isolation regions and on the device regions.

16. The device according to claim 1, wherein
a permittivity of the block insulator is higher than a permittivity of the tunnel insulator.

17. The device according to claim 1, wherein
a permittivity of the block insulator is higher than a permittivity of the insulator.

18. The device according to claim 1, further comprising:
a substrate;
a plurality of semiconductor layers stacked on the substrate, and functioning as the device regions; and
a plurality of insulating layers stacked on the substrate so as to alternate with the semiconductor layers, and functioning as isolation regions,
wherein the tunnel insulator, the charge storage layer, the block insulator, and the gate electrode are successively stacked on side surfaces and a bottom surface of a trench which is disposed on the substrate so as to penetrate the semiconductor layers and the insulating layers.

19. The device according to claim 18, wherein
the trench extends in a direction parallel to a principal plane of the substrate, and
the direction in which the trench extends is the gate length direction of the memory cell transistors.
